(19) United States
(12) Patent Application Publication
(10) Pub. No.: US 2019/0310331 A1
(43) Pub. Date: Oct. 10, 2019

(54) ARRAY COIL AND MAGNETIC RESONANCE IMAGING APPARATUS

(71) Applicant: Hitachi, Ltd., Tokyo (JP)

(72) Inventors: Yosuke OTAKE, Tokyo (JP); Yoshihisa SOTOME, Tokyo (JP); Hisaaki OCHI, Tokyo (JP)

(73) Assignee: Hitachi, Ltd., Tokyo (JP)

(21) Appl. No.: 16/374,582

(22) Filed: Apr. 3, 2019

(30) Foreign Application Priority Data
Apr. 10, 2018 (JP) 2018-075596

(51) Int. Cl. G01R 33/36; G01R 33/34

(52) U.S. Cl. CPC G01R 33/3607; G01R 33/34084; G01R 33/34046

(57) ABSTRACT

The array-coil includes a plurality of coil units that are each adjusted to receive a magnetic resonance signal from an examinee. Each coil unit includes: a first-coil-element and a second-coil-element of which each is formed of a linear conductor having flexibility with a predetermined length; and a signal detecting unit that is inserted in series between the first-coil-element and the second-coil-element and detects the magnetic resonance signal. One end of each of the first-coil-element and the second-coil-element is connected to the signal detecting unit and the other end thereof is an open end. Adjacent areas are electromagnetically coupled to each other to function by curving and arranging the first-coil-element and the second-coil-element such that at least partial areas on the open end side of the first-coil-element and the open end side of the second-coil-element are adjacent to each other with a predetermined gap therebetween.

### BACKGROUND OF THE INVENTION

### 1. Field of the Invention

The present invention relates to a magnetic resonance imagine (MRI) apparatus and more particularly to a radio-frequency (RF) coil that detects a nuclear magnetic resonance signal by emitting an RF magnetic field.

### 2. Description of the Related Art

An MRI apparatus applies an RF magnetic field to an object placed in a magnetic field (a static magnetic field) which is spatially uniform to generate nuclear magnetic resonance, detects a nuclear magnetic resonance signal which is generated in response thereto, and acquires a tomographic image by performing image processing on the detected signal.

In an MRI apparatus, a device that irradiates an object with an RF magnetic field or detects a nuclear magnetic resonance signal which is generated from the object is referred to as an RF coil. A receiving RF coil that detects a nuclear magnetic resonance signal is adjusted to resonate at the same frequency as the nuclear magnetic resonance signal and receives the nuclear magnetic resonance signal. It is preferable that the receiving RF coil be arranged to be closer to an object and along a diagnosis region of the object in order to obtain high sensitivity.

A coil unit constituting a receiving RF coil includes a coil element having flexibility and circuits that are inserted into the coil element such as a signal detecting circuit that detects a current flowing in the coil element, a frequency adjusting circuit that includes a plurality of capacitors for adjusting the resonance frequency of the RF coil, and a magnetic coupling preventing circuit that prevents magnetic coupling to a transmitting RF coil, for example, as illustrated in FIG. 14. The coil unit forms a resonance circuit using the capacitors inserted into the coil element and is adjusted to the same frequency as the magnetic resonance signal to efficiently acquire a nuclear magnetic resonance signal. At the time of acquisition of an image, receiving sensitivity is improved by curving the coil element and arranging the coil element along a diagnosis region of an object.

In the coil unit illustrated in FIG. 14, the signal detecting circuit, the frequency adjusting circuit, the magnetic coupling preventing circuit, and the capacitors are covered by a hard cover respectively in order to prevent destruction thereof due to an external impact. That is, in the coil unit illustrated in FIG. 14, since circuits requiring a hard cover are scattered in the coil element, the flexibility of the coil unit decreases. Since the number of electronic components mounted therein with an increase in the number of channels increases, the number of hardcovers further increases and thus a decrease in weight of the coil unit is difficult.

On the other hand, for example, Japanese Patent No. 4820022 discloses an RF coil of which flexibility is secured by applying a coaxial cable as a coil element. In the RF coil disclosed in Japanese Patent No. 4820022, the coaxial cable can be used as a coil element, a capacitance component of the coaxial cable can be used, and frequency adjustment can be performed by appropriately determining the type or the length of the coaxial cable.

However, in the RF coil disclosed in Japanese Patent No. 4820022, since a frequency adjusting circuit is required, the frequency adjusting circuit needs to be covered by a cover and thus it cannot be said that a decrease in weight or improvement in flexibility is satisfactory. The types of the coaxial cable are limited, and the size of the coil which can be embodied and frequency adjustment thereof are limited in consideration of the number of channels of an RF coil to be described, the size of an examination object, and the like. Accordingly, it may be difficult to adjust the frequency of an RF coil with an arbitrary size in the RF coil disclosed in Japanese Patent No. 4820022.

### SUMMARY OF THE INVENTION

The invention has been made in consideration of the above-mentioned circumstances and an objective thereof is to provide an array coil that has high flexibility and a small weight and can easily perform frequency adjustment.

The invention provides the following configurations to achieve the above-mentioned objective.

According to an aspect of the invention, there is provided an array coil including a plurality of coil units that are each adjusted to receive a magnetic resonance signal from an examinee, in which each coil unit includes: a first coil element and a second coil element of which each is formed of a linear conductor having flexibility with a predetermined length; and a signal detecting unit that is inserted in series between the first coil element and the second coil element and detects the magnetic resonance signal, in which one end of each of the first coil element and the second coil element is connected to the signal detecting unit and the other end thereof is an open end, and in which adjacent areas are electromagnetically coupled to each other to function by curving and arranging the first coil element and the second coil element such that at least partial areas on the open end side of the first coil element and the open end side of the second coil element are adjacent to each other with a predetermined gap therebetween.

According to another aspect of the invention, there is provided a magnetic resonance imaging apparatus including: a static magnetic field forming unit that forms a static magnetic field; a gradient magnetic field forming unit that forms a gradient magnetic field; a transmitting RF coil that irradiates an examination object placed in the static magnetic field with an RF magnetic field; a receiving RF coil that detects a nuclear magnetic resonance signal from the examination object; and a signal processing unit that processes the nuclear magnetic resonance signal detected by the receiving RF coil, in which the receiving RF coil is the above-mentioned array coil.

According to the aspects of the invention, it is possible to provide an array coil that has high flexibility and a small weight and can easily perform frequency adjustment.

### BRIEF DESCRIPTION OF THE DRAWINGS

FIGS. 1A and 1B are diagrams illustrating an appearance of an MRI apparatus according to an embodiment of the invention, where FIG. 1A illustrates an appearance of a horizontal magnetic field type MRI apparatus and FIG. 1B illustrates an appearance of a vertical magnetic field type MRI apparatus;

FIG. 2 is a block diagram schematically illustrating a configuration of the MRI apparatus;

FIG. 3 is a diagram illustrating connection between a transmitting RF coil and a receiving RF coil in the MRI apparatus according to the embodiment of the invention;

FIG. 4A is a diagram illustrating a configuration of a birdcage RF coil which is used as the transmitting RF coil and FIG. 4B is a diagram illustrating an example of a transmitting-receiving magnetic coupling preventing circuit of the transmitting RF coil;

FIG. 5 is a diagram illustrating an example of a coil unit which is applied to an array coil which is used as the receiving RF coil;

FIG. 6A is a reference diagram illustrating a state in which coil elements of the coil unit illustrated in FIG. 5 are stretched, FIG. 6B is a graph illustrating a voltage distribution which is generated in the coil elements when a signal detecting unit has detected a signal in FIG. 6A, FIG. 6C is a reference diagram illustrating an example in which the coil elements in the coil unit function as capacitor components, and FIG. 6D illustrates an equivalent circuit of the coil unit illustrated in FIG. 6C;

FIG. 7 is a reference diagram illustrating a part of an array coil which has multiple channels by providing a plurality of coil units;

FIG. 8 is a reference diagram illustrating an example in which the length of the coil elements is changed;

FIGS. 9A and 9B are reference diagrams illustrating coil elements in which a conductor sheet is provided as a frequency-adjustment conductor;

FIG. 10 is a reference diagram illustrating an arrangement position relationship between an examination object and a coil unit at the time of simulation;

FIGS. 11A to 11C illustrate the simulation results associated with measurement of sensitivity of the coil unit illustrated in FIG. 5, where FIG. 11A illustrates a sensitivity distribution in an XY plane passing through the coil center of the coil unit according to the embodiment, FIG. 11B illustrates a sensitivity distribution of the XY plane passing through the coil center of a coil unit according to the related art, and FIG. 11C illustrates a profile of a Y-direction line passing through the coil centers in FIGS. 11A and 11B;

FIGS. 12A and 12B are reference diagrams illustrating a coil unit according to a modified example of the embodiment;

FIG. 13A is a reference diagram illustrating an equivalent circuit of the coil unit illustrated in FIGS. 12A and 12B and FIG. 13B is a reference diagram illustrating an equivalent circuit of a coil unit according to the related art; and

FIG. 14 is a reference diagram illustrating a coil unit according to the related art.

### DETAILED DESCRIPTION OF THE INVENTION

Hereinafter, an MRI apparatus to which an RF coil (an array coil) according to an embodiment of the invention is applied will be described with reference to the accompanying drawings. In the drawings associated with embodiments and examples, the same elements will be referred to by the same reference signs and description thereof will not be repeated.

<Entire Configuration of MRI Apparatus>

First, an MRI apparatus to which an RF coil according to the embodiment can be applied will be described below.

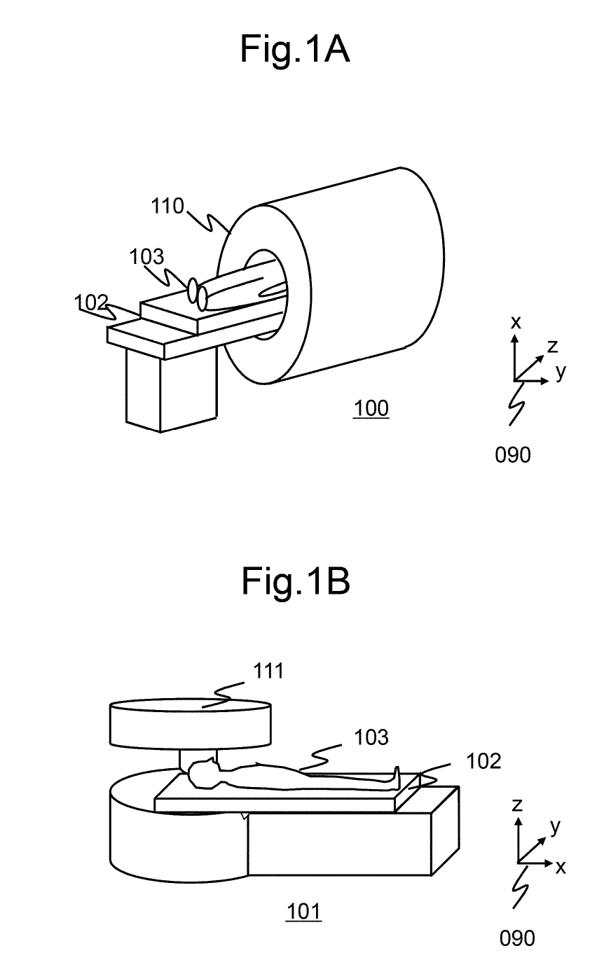

FIGS. 1A and 1B illustrate appearances of examples of the MRI apparatus. Particularly, FIG. 1A illustrates a horizontal magnetic field type MRI apparatus 100 using a tunnel magnet 110 that generates a static magnetic field using a solenoid coil.

FIG. 1B illustrates an open vertical magnetic field type MRI apparatus 101 in which a magnet 111 is separated vertically to enhance openness. These MIR apparatuses 100 and 101 include a table 102 on which an examination object (an examinee) 103 is placed. In a state in which the examinee 103 is placed on the table, the examinee is arranged in an examination space in which a uniform magnetic field (a static magnetic field) is generated by the magnet 110 or 111. The magnet 110 or 111 constitutes a static magnetic field forming unit that forms a static magnetic field.

A so-called multichannel RF coil including a plurality of coil units can be applied to these MRI apparatuses and the RF coil according to the embodiment can also be applied to any of the horizontal magnetic field type MRI apparatus 100 and the vertical magnetic field type MRI apparatus 101.

The MRI apparatuses illustrated in FIGS. 1A and 1B are merely examples, and the invention can employ various known MRI apparatuses regardless of the form or type of the apparatuses. In the following description, a coordinate system 090 in which a static magnetic field direction is defined as a z direction and two directions perpendicular thereto are defined as an x direction and a y direction is used as a coordinate system which is common to the horizontal magnetic field type and the vertical magnetic field type.

An example in which a horizontal magnetic field type MRI apparatus is applied to the embodiment will be described below to describe a schematic configuration of the MRI apparatus 100.

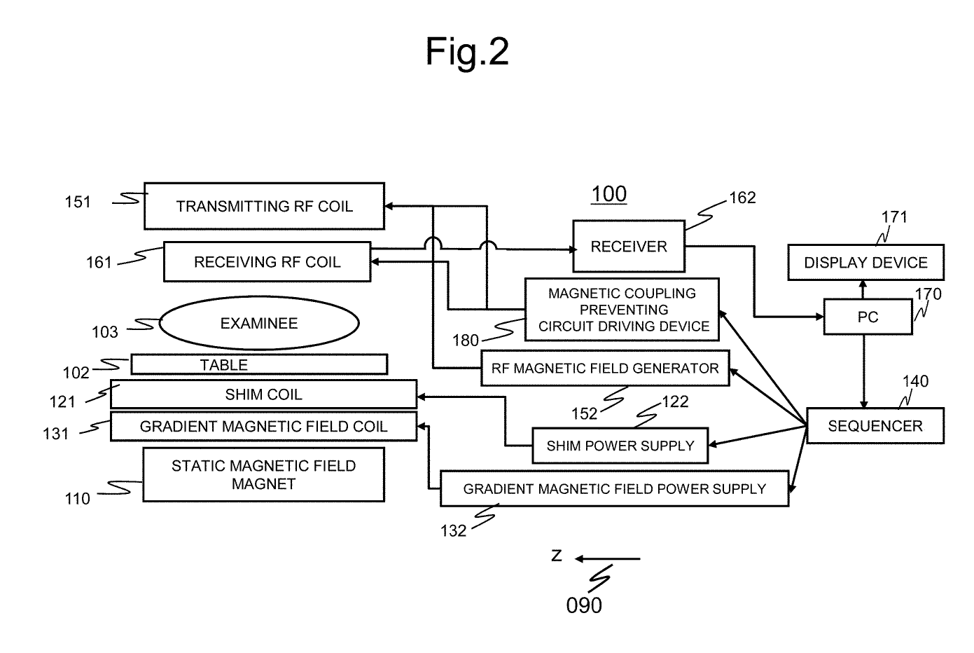

As illustrated in FIG. 2, the MRI apparatus 100 includes a horizontal magnetic field type magnet (a static magnetic field magnet) 110, a gradient magnetic field coil 131, a transmitting RF coil 151, a receiving RF coil 161, a gradient magnetic field power supply 132, a shim coil 121, a shim power supply 122, an RF magnetic field generator 152, a receiver 162, a magnetic coupling preventing circuit driving device 180, a computer (PC) 170, a sequencer 140, and a display device 171. Reference numeral 102 denotes a table on which an examination object (an examinee) 103 is placed.

The gradient magnetic field coil 131 is connected to the gradient magnetic field power supply 132 and generates a gradient magnetic field. The gradient magnetic field coil 131 and the gradient magnetic field power supply 132 constitute a gradient magnetic field forming unit that forms a gradient magnetic field. The shim coil 121 is connected to the shim power supply 122 and adjusts uniformity of a magnetic field. The transmitting RF coil 151 is connected to the RF magnetic field generator 152 and applies (transmits) an RF magnetic field to an examinee 103.

The receiving RF coil 161 is connected to the receiver 162 and receives a nuclear magnetic resonance signal from the examinee 103. Here, a multichannel RF coil (hereinafter referred to as an array coil) including a plurality of coil units is applied as the receiving RF coil 161 according to this embodiment. In the following description, it is assumed that the number of coil units constituting the array coil and the number of channels are the same. Details of the array coil as the receiving RF coil 161 will be described later.

The magnetic coupling preventing circuit driving device 180 is connected to a magnetic coupling preventing circuit (which will be described ter). The magnetic coupling preventing circuit is a circuit that is connected to the transmitting RF coil 151 and the receiving RE coil 161 and prevents magnetic coupling between the transmitting RF coil 151 and the receiving RF coil 161.

The sequencer 140 sends commands to the gradient magnetic field power supply 132, the RF magnetic field generator 152, and the magnetic coupling preventing circuit driving device 180 to operate them. A command is issued in accordance with an instruction from the computer (PC) 170. In accordance with an instruction from the computer (PC) 170, a magnetic resonance frequency which serves as a reference for detection is set by the receiver 162. For example, in accordance with a command from the sequencer 140, an RF magnetic field is applied to the examinee 103 via the transmitting RF coil 151. A nuclear magnetic resonance signal which is generated from the examinee 103 in response to application of the RF magnetic field is detected by the receiving RF coil 161 and detection thereof is performed by the receiver 162.

The computer (PC) 170 performs control of the entire operation of the MRI apparatus 100 and various signal processing. For example, the computer (PC) 170 receives a signal detected by the receiver 162 via an A/D conversion circuit and performs signal processing such as image reconstruction (a function of an image reconstructing unit). The result is displayed on the display device 171. The detected signals or measuring conditions are stored in a storage medium if necessary. The computer (PC) 170 causes the sequencer 140 to issue a command such that the devices operate at pre-programmed times and strength. When it is necessary to adjust static magnetic field uniformity, the computer (PC) 170 causes the sequencer 140 to issue a command to the shim power supply 122 such that the shim coil 121 adjusts the static magnetic field uniformity.

<Outline of Transmitting RF Coil and Receiving RF Coil>

As described above, two types of RF coils such as the transmitting RF coil 151 and the receiving RF coil 161 are used in the MRI apparatus. Regarding the transmitting RF coil 151 and the receiving RF coil 161, one RF coil may serve as both RF coils or separate RF coils may be used.

A case in which the transmitting RF coil 151 and the receiving RF coil 161 are separate coils, the transmitting RE′ coil 151 is an RF coil having a birdcage shape (a birdcage RF coil), and the receiving RF coil 161 is a multichannel array coil including a plurality of RF coils will be exemplified below to describe details of the RF coils.

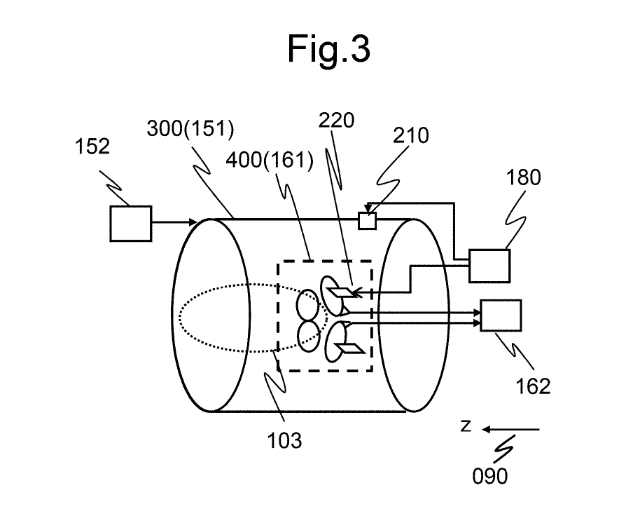

First, the arrangement of a birdcage RF coil 300 which is used as the transmitting RF coil 151 and an array coil 400 which is used as the receiving RF coil 161 and connection forms of the birdcage RF coil 300, the array coil 400, the RF magnetic field generator 152, the receiver 162, and the magnetic coupling preventing circuit driving device 180 will be described with reference to FIG. 3.

As illustrated in FIG. 3, the birdcage RF coil 300 has a substantially cylinder-shaped appearance (which includes an elliptical pillar or a polygonal pillar) and is arranged such that an axis of the cylindrical pillar is coaxial with a center axis (an axis in the Z direction) of the magnet 110. An examinee 103 is disposed inside the birdcage BY coil 300. The array coil 400 is disposed close to the examinee 103 inside the birdcage RF coil 300. As described above, the birdcage RF coil 300 is connected to the RF magnetic field generator 152. The array coil 400 is connected to the receiver 162.

A magnetic coupling preventing circuit 210 that prevents magnetic coupling to the array coil 400 is provided in the birdcage RF coil 300, and a magnetic coupling preventing circuit 220 that prevents magnetic coupling to the birdcage RF coil 300 is provided in the array coil 400. These circuits are referred to as transmitting-receiving magnetic coupling preventing circuits. By using the transmitting-receiving magnetic coupling preventing circuits, transmission of an RF magnetic field and reception of a nuclear magnetic resonance signal are possible without being coupled to each other in the above-mentioned arrangement.

[Transmitting RF Coil]

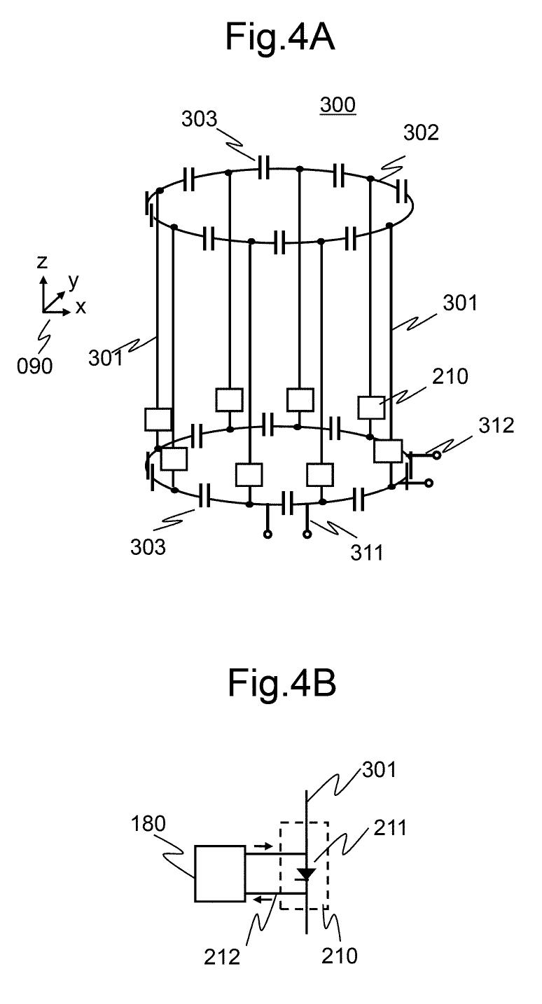

The birdcage RF coil 300 which is used as the transmitting RF coil 151 according to this embodiment will be described below with reference to FIG. 4.

The birdcage RF coil 300 according to this embodiment is adjusted such that a resonance frequency thereof is the resonance frequency of an element to be excited (magnetic resonance frequency), and emits an RF magnetic field of the magnetic resonance frequency. In this embodiment, the resonance frequency is adjusted to the magnetic resonance frequency f0 of a hydrogen nucleus at which hydrogen nuclei can be excited. In the following description, the magnetic resonance frequency of an RF magnetic field which is emitted is defined as f0.

FIG. 4A is a block diagram illustrating the configuration of the birdcage RF coil 300 according to this embodiment. As illustrated in the drawing, the birdcage RF coil 300 according to this embodiment includes a plurality of straight conductors 301, end conductors 302 that connects ends of the straight conductors 301, and capacitors 303 that are inserted into the end conductors 302.

The birdcage RF coil 300 includes two input ports 311 and 312. Transmission signals with phases different by 90 degrees are input to the first input port 311 and the second input port 312, and the birdcage RF coil 300 is configured to efficiently apply an RF magnetic field to the examinee 103.

In the birdcage RF coil 300 according to this embodiment, the transmitting-receiving magnetic coupling preventing circuit 210 that prevents magnetic coupling to the receiving RF coil 161 (the array coil 400) is inserted in series in the straight conductors 301 of the birdcage RF coil 300.

The transmitting-receiving magnetic coupling preventing circuit 210 can be formed of a PIN diode 211 which is inserted into the straight conductor 301, for example, as illustrated in FIG. 4B, and a control signal line 212 is connected to both ends of the PIN diode 211. The control signal line 212 is connected to the magnetic coupling preventing circuit driving device 180. It is preferable that a choke coil (not illustrated) be inserted into the control signal line 212 in order to avoid mixing of radio-frequency waves.

The PIN diode 211 has characteristics that it normally exhibits high resistance (OFF) and is substantially turned on (ON) when a value of a DC current flowing forward in the PIN diode 211 is equal to or greater than a predetermined value. In this embodiment, ON/OFF of the PIN diode 211 is controlled with a DC current output from the magnetic coupling preventing circuit driving device 180 using these characteristics. That is, when an RF signal is transmitted, a control current for turning on the PIN diode 211 flows therein via the control signal line 212 and the birdcage RF coil 300 functions as the transmitting RF coil 151. When a nuclear magnetic resonance signal is received, the control current is stopped and the birdcage RF coil 300 is switched to an open state in which impedance thereof is high.

In this way, in this embodiment, by controlling the DC current (the control current) from the magnetic coupling preventing circuit driving device 180, the birdcage RF coil 300 serves as the transmitting RF coil 151 at the time of transmitting an RF signal and is switched to the open state to remove magnetic coupling to the array coil 400 which is the receiving RF coil 161.

[Receiving RF Coil]

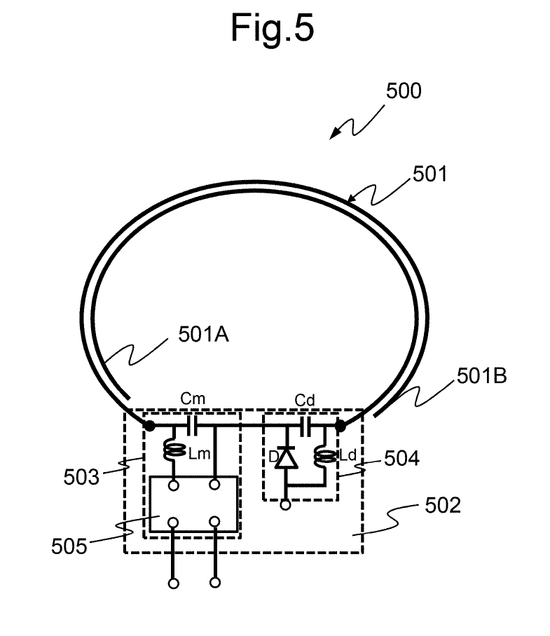

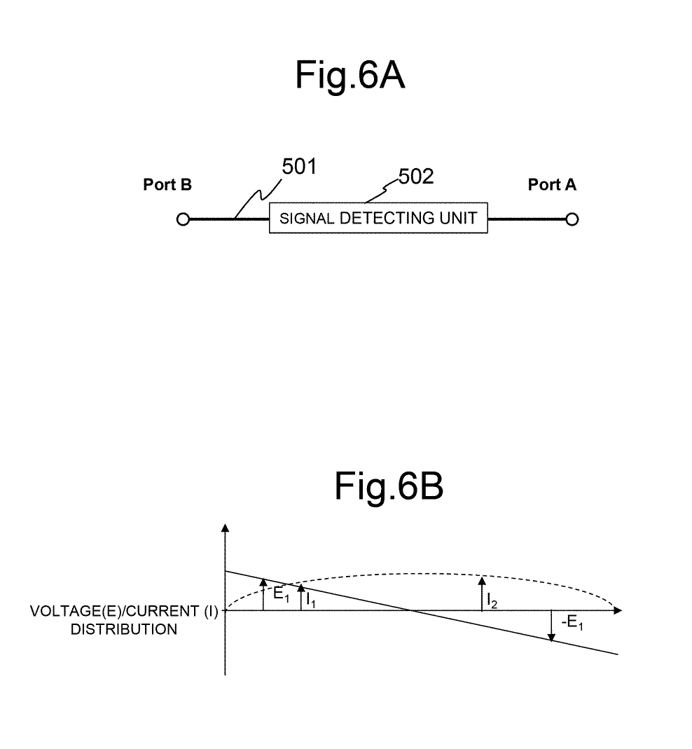

The receiving RF coil 161 according to this embodiment will be described below with reference to FIGS. 5 to 6D.

FIG. 5 illustrates one coil unit constituting the array coil which is the receiving RF coil 161. A coil unit 500 includes a first coil element 501A and a second coil element 501B of which each is formed of a linear conductor with flexibility and a signal detecting unit 502 that is inserted between the first coil element 501A and the second coil element 501B and detects a magnetic resonance signal.

One end of the first coil element 501A is connected to the signal detecting unit 502 and the other end thereof is an open end. Similarly, one end of the second coil element 501B is connected to the signal detecting unit 502 and the other end thereof is an open end. The open end of the first coil element 501A and the open end of the second coil element 501E are insulated. The total length of the first coil element 501A and the second coil element 501B is equal to or less than half the wavelength of the magnetic resonance frequency.

The coil unit 500 forms a dipole antenna having a ring shape using the first coil element 501A and the second coil element 501B (hereinafter referred to as “coil elements 501” when both of the first coil element 501A and the second coil element 501B are intended) and the signal detecting unit 502.

Each coil unit 500 constituting the array coil is adjusted such that reception of a nuclear magnetic resonance signal is possible and each coil unit serves as one channel. Signals received by the coil units are sent to the receiver 162.

In the example illustrated in FIG. 5, the first coil element 501A and the second coil element 501B have the substantially same length and the signal detecting unit 502 is located at the substantially central portion of the coil elements 501. An area on the open end side of the first coil element 501A and an area on the open end side of the second coil element 501B are curved to the vicinity of the signal detecting unit 502 to form a ring shape, and the first coil element 501A and the second coil element 501B are arranged to be adjacent to each other in an area other than the signal detecting unit 502. In the coil elements 501, the adjacent areas are electromagnetically coupled to function.

For example, a cable in which a wire is coated with an insulator can be applied as the coil elements 501. In this case, the coil elements may be overlapped such that the insulators are in contact with each other in adjacent areas of the coil elements 501. In addition, the coil elements 501 may be curved and arranged such that both open ends are adjacent to each other with a constant distance maintained therebetween.

The principle in which the coil units 500 having the above-mentioned configuration resonates at the magnetic resonance frequency and receive a magnetic resonance signal will be described below.

On the basis of the fact that the sensitivity of the coil unit 500 is equivalent to the magnetic field strength which is generated when an RF signal with unit power is applied to the coil unit 500 in the reciprocity theorem, the operating principle of the coil unit 500 will be described below with reference to the operation when an RF signal is applied to the signal detecting unit 502 of the coil unit 500.

FIG. 6A illustrates a state in which the coil elements 501 curved in a ring shape in the coil unit 500 are stretched. That is, the coil unit is a dipole antenna in which the first coil element 501A is provided at one end there, the second coil element 501B are provided at the other end thereof with the signal detecting unit 502 interposed therebetween, and the coil elements 501 extend symmetrically with respect to the signal detecting unit 502. The open end of the first coil element 501A is defined as PortA (the right part of FIG. 6A) and the open end of the second coil element 501B is defined as PortB (the left part of FIG. 6A).

In the coil unit 500, when an RF signal is applied to the signal detecting unit 502, a voltage distribution and the current distribution illustrated in FIG. 6B are generated in the coil element 501. Specifically, since no current flows at the open end of the first coil element 501A and the open end of the second coil element 501B, a high voltage is applied therebetween, a plus voltage is generated at one end, and a minus voltage is generated at the other end. In the example illustrated in FIG. 6A, the voltage of the open end PortB is plus and the voltage of the open end PortA is minus. In the voltage distribution, the voltages at the open ends are the highest and the voltages decrease from the open ends toward the signal detecting unit 502. On the other hand, currents in the same direction flow in the first coil element 501A and the second coil element 501B.

Accordingly, in the coil elements 501 curved in a ring shape, a potential difference, that is, a line capacitance, is generated between areas of the coil elements 501 disposed to be adjacent to each other and this serves as a capacitance component (Cc1). At the same time, the currents flow in the first coil element 501A and the second coil element 501B generate magnetic fields Φ1 and Φ2, which are magnetically coupled to each other in synchronization with each other. In this embodiment, since the line capacitance has a dominant value, the circuit illustrated in FIG. 6C is obtained. As a result, the coil unit according to this embodiment can be expressed by an equivalent circuit illustrated in FIG. 6D. The line capacitance can be adjusted using the arrangement position of the first coil element 501A and the second coil element 501B.

The coil elements 501 that functions as a conductor portion having an inductance component and a capacitor inserted thereinto as illustrated in FIG. 6D and can constitute an LC resonance circuit. Accordingly, the coil unit 500 can acquire a magnetic resonance signal by resonating at the same frequency as the magnetic resonance frequency.

Referring back to FIG. 5, the signal detecting unit 502 includes a signal detecting circuit 503 and a magnetic coupling preventing circuit 504 in order to detect a magnetic resonance signal from an examinee which is received by the coil elements 501. The signal detecting circuit 503 includes a first capacitor Cm, a first inductor Lm, and a signal amplifier 505, the first inductor Lm and the signal amplifier 505 are connected in series to each other, and the first inductor Lm and the signal amplifier 505 are connected in parallel to the first capacitor Cm. The first capacitor Cm is connected in series to the coil elements 501.

A parallel resonance circuit which is constituted by the first capacitor Cm, the first inductor Lm, and the signal amplifier 505 in the signal detecting circuit 503 forms a magnetic coupling preventing circuit that prevents magnetic coupling between the coil units by adjustment for matching the resonance frequency of the receiving RF coil 161.

The magnetic coupling preventing circuit 504 includes a second capacitor Cd, a second inductor Ld, and a diode D serving as a switch. In the magnetic coupling preventing circuit 504, the second inductor Ld and the diode D are connected in series to each other, and the second capacitor Cd is connected in parallel to the second inductor Ld and the diode D. The second capacitor Cd is connected in series to the coil elements 501.

The diode D is connected to the magnetic coupling preventing circuit driving device 180, and a parallel resonance circuit constituted by the second inductor Ld and the diode D prevents magnetic coupling between the transmitting RF coil 151 and the receiving RF coil 161 by adjustment for matching the resonance frequency of the coil unit when the diode D is turned on. When the magnetic coupling preventing circuit 504 does not operate, the corresponding coil unit 500 operates as a receiving coil.

The circuit seen from the signal amplifier 505 is adjusted to resonate at the magnetic resonance frequency of the MRI apparatus and is adjusted to receive a magnetic resonance signal. The signal detecting unit 502 is adjusted to an input impedance in which noise is minimized when the signal amplifier 505 is connected thereto.

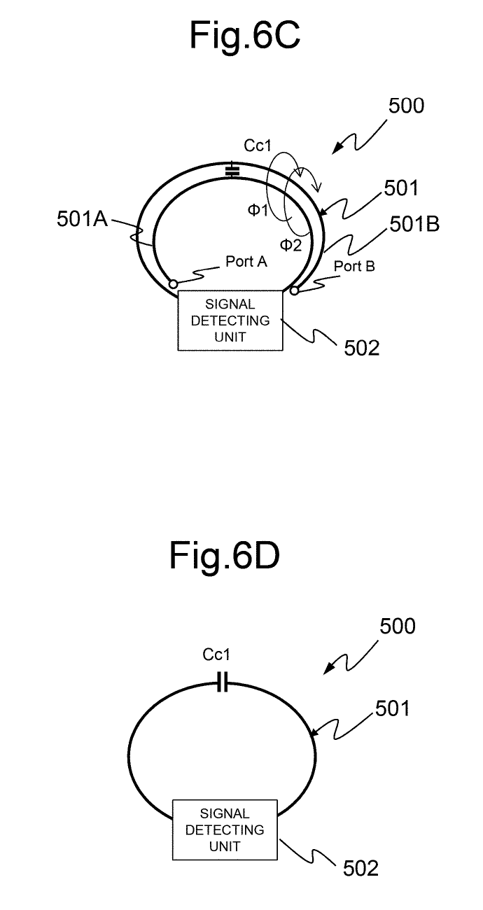

When a plurality of coil units for multiple channels are provided in the array coil, the coil elements 501 are arranged to partially overlap each other such that they are not magnetically coupled to each other (FIG. 7).

Procedures of adjusting the circuit elements in the coil unit 500 having the above-mentioned configuration will be described below.

In the following description, for example, it is assumed that the coil unit 500 is adjusted to resonate at the magnetic resonance frequency 128 MHz (f0=128 MHz) of a hydrogen nucleus with static magnetic field strength of 3 T (tesla). It is also assumed that the first coil element 501A and the second coil element 501B are linear wires with a diameter of 1 mm in which the total length of the first coil element 501A and the second coil element 501B is 35 cm, and the signal detecting unit 502 is inserted into the center position between the first coil element 501A and the second coil element 5015.

In the coil unit 500, an area on the open end side of the first coil element 501A and an area on the open end side of the second coil element 501B in the coil unit 500 are arranged such that partial areas thereof are adjacent to each other, and the coil elements are curved in a circular ring shape with a diameter of 11 cm. Specifically, the coil elements 501 are arranged to form two turns of loops. The gap between the adjacent areas of the coil elements is set to 2 mm.

In the coil unit 500, the resonance frequency of the coil unit 500 when seen from the signal amplifier 505 is adjusted to 128 MHz which is synchronized with the magnetic resonance signal, and the input impedance of the coil unit 500 is adjusted to 50Ω to minimize noise.

Specifically, the value of the second capacitor Cd is adjusted to adjust the resonance frequency to 128 MHz. In addition, the value of the first capacitor Cm is adjusted to adjust the input impedance of the oil to 50Ω. In general, the impedance increases when the value of the first capacitor Cm decreases, and the impedance decreases when the value of the first capacitor Cm increases. Therefore, adjustment is performed such that the resonance frequency is finally 128 MHz and the impedance is finally 50Ω by alternately repeating adjustment of the values of the second capacitor Cd and the first capacitor Cm.

Subsequently, the second inductor Ld is adjusted such that the coil unit 500 is open at the time of driving the magnetic coupling preventing circuit 504 according to the value of the second capacitor Cd. The first inductor Lm of the magnetic coupling preventing circuit employing a preamplifier is adjusted according to the value of the first capacitor Cm.

In the coil unit 500 according to this embodiment, that is, in the coil unit 500 with a ring shape in which the first coil element 501A and the second coil element 501B of which each is formed of a linear wire with a diameter of 1 mm and a length of 35 cm are curved and the gap between the adjacent areas of the coil elements is 2 mm, and the diameter is 11 cm, the value of the first capacitor Cm is 180 pF and the value of the second capacitor Cd is 18 pF.

Through this adjustment, the coil unit 500 according to this embodiment can receive a magnetic resonance signal. The receiving coil is not magnetically coupled to the transmitting coil and the receiving coils are not magnetically coupled to each other.

As described above, in the coil unit 500 according to this embodiment, adjustment of the resonance frequency is performed by adjusting the value of the second capacitor Cd, but the invention is not limited thereto. In another adjustment method, for example, the resonance frequency may be changed by changing the gap between the adjacent areas of the first coil element 501A and the second coil element 501B.

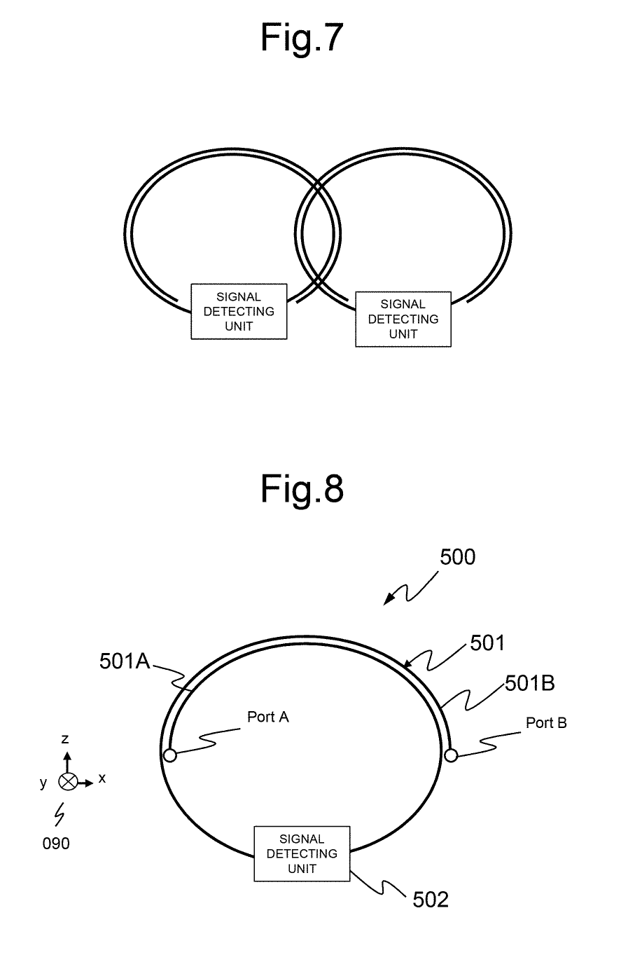

As illustrated in FIG. 8, the resonance frequency may be changed by decreasing the length of the coil elements 501 to decrease the adjacent areas. By employing this adjustment method, it is possible to form a coil unit with an arbitrary size.

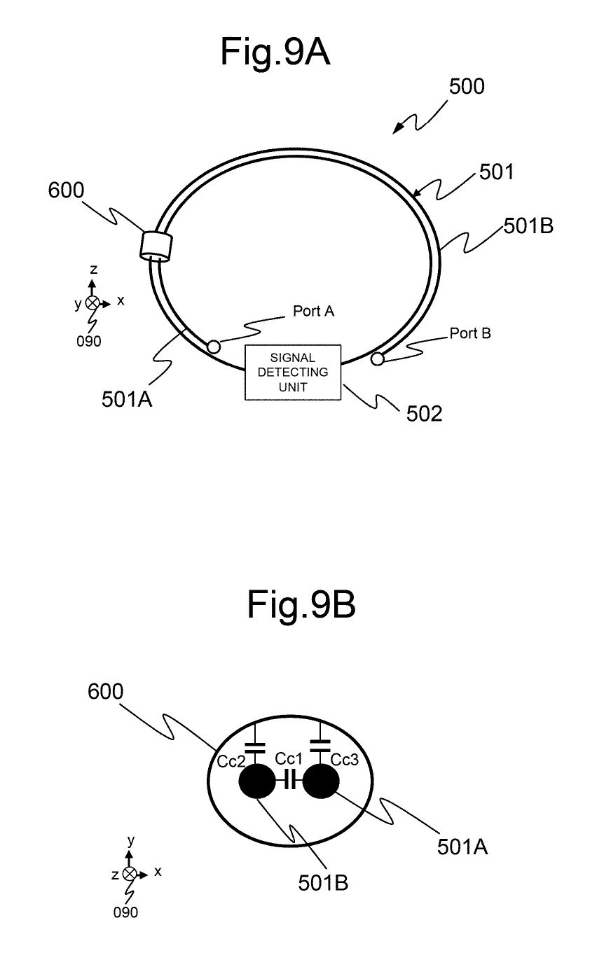

As illustrated in FIGS. 9A and 9B, the resonance frequency may be adjusted by applying a conductor sheet 600 as the frequency-adjustment conductor. As illustrated in FIGS. 9A and 9B, the conductor sheet 600 is wound on the coil unit 500 such that it does not come into contact with the coil elements 501. Accordingly, in addition to a capacitance Cc1 which is generated between the coil elements of the coil unit 500, since the combined capacitance of the capacitors vary by a capacitance component Cc2 generated between the open end PortB side and the conductor sheet 600 and a capacitance component Cc3 generated between the open end PortA side and the conductor sheet 600, it is possible to change the resonance capacitance.

Since the voltage of the coil elements 501 varies depending on the position, the capacitance component Cc2 and the capacitance component Cc3 can vary depending on the position at which the conductor sheet is provided. Accordingly, the combined capacitance of the capacitors can be changed by appropriately changing the position of the conductor sheet 600 which is provided in the coil unit 500. That is, it is possible to adjust a frequency by causing the conductor sheet to slide on the coil elements 501.

The combined capacitance of the capacitors can be changed by changing the distance between the conductor sheet 600 and the coil elements 501, and the resonance frequency can also be adjusted.

In this way, since the resonance frequency can be reversibly adjusted with good reproducibility by disposing the conductor sheet 600 to be movable on the coil elements, it is possible to easily form the coil unit.

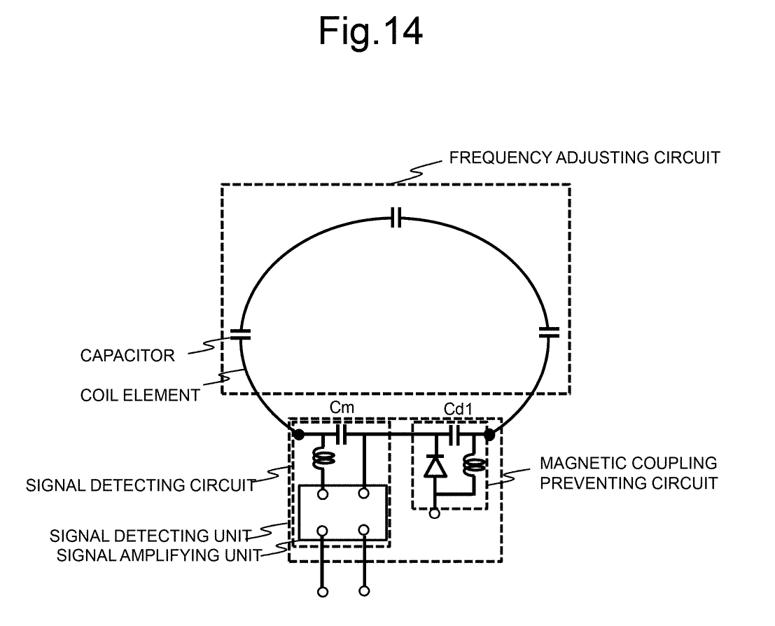

A result of a simulation for comparison in sensitivity between the coil unit 500 according to this embodiment and the coil unit according to the related art illustrated in FIG. 14 will be described below.

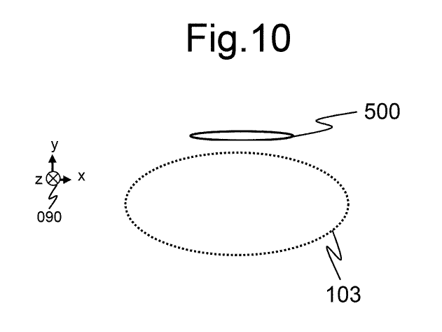

As illustrated in FIG. 10, the coil unit 500 is disposed above an examinee 103 and sensitivity thereof is measured.

In the coil unit according to the related art (see FIG. 14) which is a reference for comparison, a wire with a diameter of 1.4 mm is applied such that the weight of the coil elements are the same as that of the coil unit 500 according to this embodiment.

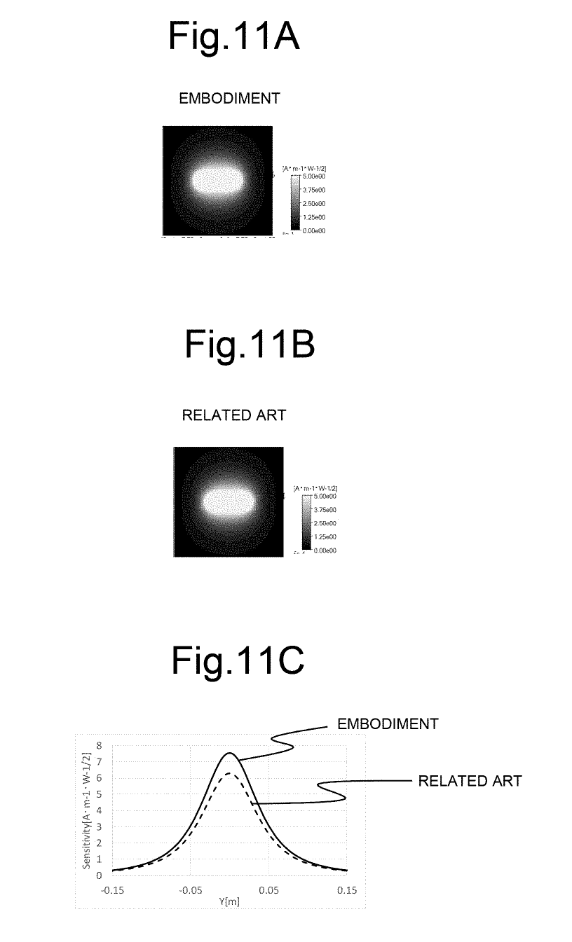

As illustrated in FIG. 10, the coil unit 500 is disposed above an examinee 103, sensitivity thereof is measured, and sensitivity distribution which the measured result is illustrated in FIGS. 11A to 11C. FIG. 11A illustrates a sensitivity distribution in an XY plane passing through the coil center of the coil unit according to this embodiment and FIG. 11B illustrates a sensitivity distribution of the XY plane passing through the coil center of the coil unit according to the related art. FIG. 11C illustrates a profile of a Y-direction line passing through the coil centers in FIGS. 11A and 11B, where a solid line indicates the profile of the sensitivity distribution of the coil unit according to this embodiment and a dotted line indicates the profile of the sensitivity distribution of the coil unit according to the related art.

From the result of simulation illustrated in FIGS. 11A to 11C, it can be seen that the coil unit according to this embodiment has more excellent sensitivity than the coil unit according to the related art. This is because two coil elements 501A and 502B are efficiently electromagnetically coupled to each other and a loss decreases.

In this way, in the coil unit according to this embodiment, since a capacitor is not inserted into the coil elements unlike the coil unit according to the related art illustrated in FIG. 14, it is not necessary to provide a hard cover for circuit protection and thus an increase in weight or damage in flexibility of the coil elements due to a hard cover is not caused.

Accordingly, it is possible to decrease the weight and to improve flexibility in comparison with the coil unit according to the related. As can also be seen from the result of simulation, the coil elements according to this embodiment can accurately receive a magnetic resonance signal with sensitivity equal to or greater than that in the coil unit according to the related art.

Particularly, for example, when a cable in which a wire is coated with an insulator or the like is applied to the coil elements 501, the distance between the adjacent coil elements is kept constant and thus it is possible to reduce variation of the resonance frequency and to stably receive a magnetic resonance signal. In this case, the wire in the cable is not necessarily one wire, and may be a stranded wire in which a plurality of wires are stranded. In this case, the flexibility of the wire is improved. The line capacitance or the loss can be optimized by selecting the insulator. For example, when fluorine is used as the insulator, a line capacitor with a low loss can be formed.

A two-core cable may be used as the coil elements. Out of two cores of the two-core cable, one core at one end of the two-core cable is connected to the signal detecting unit and the other core at the other end of the two-core cable is connected to the signal detecting unit. Accordingly, the same circuit configuration as the coil unit according to this embodiment can be obtained by employing a two-core cable. When a two-core cable is employed in this way, the process of arranging the coil elements to be adjacent to each other is not necessary, and thus reproducibility of coil formation can be improved and the coil unit can be easily formed.

In the above-mentioned embodiment or the like, a wire is employed as a coil element, but the wire may not be a linear wire and the cross-sectional shape of the wire may not be substantially circular. For example, a sheet-shaped or ribbon-shaped conductor may be employed, and the line capacitance generated between the coil elements can be adjusted and the resonance frequency can also be adjusted by appropriately selecting the thickness, the diameter, the width, and the like of the conductor which is employed as the coil element.

The lengths of the first coil element 501A and the second coil element 501B are the same, but may not be the same as long as partial areas of the elements are adjacent to each other in a region of the ring-shaped elements other than the signal detecting unit 502.

The coil unit is not limited to the substantially circular ring shape illustrated in FIG. 5 or the like. A coil shape suitable for the purpose such as a rectangular shape or a butterfly coil of an 8 shape can be selected by curving or bending the coil elements such that the adjacent areas are formed at the open ends of the coil elements to cause a part of the coil elements to function as a capacitor.

The coil unit according to this embodiment can form an array coil including a plurality of coil units according to this embodiment and may also form an array coil in which the coil unit according to this embodiment is combined with the coil unit according to the related art illustrated in FIG. 14. By combining various coils, the coil unit can be applied to form an optimal array coil suitable for an examinee.

### Modified Example

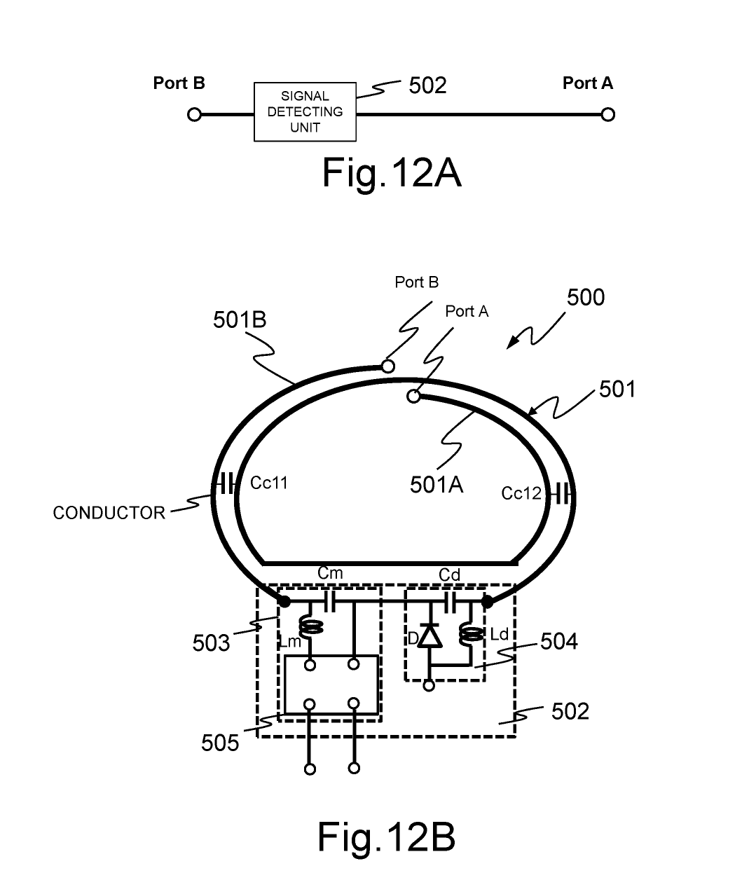

A modified example of the above-mentioned embodiment will be described below with reference to FIGS. 12A and 12B.

In the above-mentioned embodiment, the coil unit 500 is formed in a ring shape in which the open ends of the first coil element 501A and the second coil element 501B are adjacent to each other in an area other than the signal detecting unit 502 by inserting the signal detecting unit 502 between the first coil element 501A and the second coil element 501B having the same length and curving the open ends of the first coil element 501A and the second coil element 501B. That is, the signal detecting unit 502 is located at the center of the coil elements 501.

On the other hand, in this modified example, a ring shape in which a partial area of the first coil element 501A or the second coil element 501B is adjacent to the signal detecting unit 502 is formed by inserting the signal detecting unit 502 between the first coil element 501A and the second coil element 501B having different lengths and curving the open ends of the first coil element 501A and the second coil element 501B.

More specifically, in the example illustrated in FIGS. 12A and 12B, the second coil element 501B having a length smaller than that of the first coil element 501A is applied to the coil unit. Then, the open end sides of the first coil element 501A and the second coil element 501B are curved to form a ring shape in which a partial area of the first coil element 501A is adjacent to the signal detecting unit 502 and the open end of the first coil element 501A and the open end of the second coil element 501B are arranged to face each other. In an area in which the coil elements are adjacent to each other, a line capacitance and a magnetic field are generated similarly to the above-mentioned embodiment and thus the capacitor C functions dominantly.

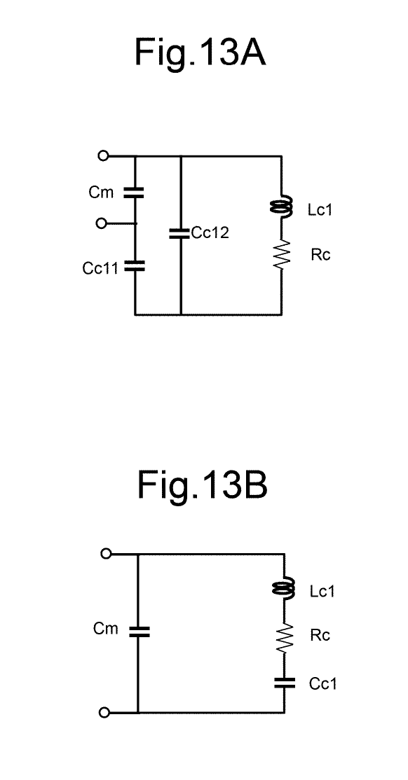

In this modified example, since the signal detecting unit 502 and the coil elements are arranged to be adjacent to each other, the capacitance component is divided into two capacitors components with respect to the signal detecting unit 502. These capacitors are illustrated as a capacitor Cc11 and a capacitor Cc12 in FIG. 12B. An equivalent circuit of FIG. 12B is illustrated in FIG. 13A. An equivalent circuit of the coil unit according to the related art illustrated in FIG. 14 is illustrated as a reference for comparison in FIG. 13B. In the equivalent circuits illustrated in FIGS. 13A and 13B, only the first capacitor Cm of the signal detecting circuit is illustrated in the signal detecting unit 502 and the other circuit components are not illustrated.

The magnetic coupling preventing circuit in the coil unit will be described now.

In the coil unit 500 according to the above-mentioned embodiment (FIG. 5) and the coil unit according to the related art (FIG. 14), the magnetic coupling preventing circuit of the receiving coil is included in the signal detecting unit 502.

Specifically, in the coil unit 500 illustrated in FIG. 5, since the parallel resonance circuit including the first capacitor Cm, the first inductor Lm, and the signal amplifier 505 is adjusted to resonate at the same frequency as the coil unit, the first capacitor Cm has high impedance from the viewpoint of the coil elements and the parallel resonance circuit operates as the magnetic coupling preventing circuit.

Accordingly, even when magnetic coupling occurs and a magnetic coupling current is generated in the coil elements of another coil unit, the generated current does not flow and magnetic coupling does not occur because both ends of the first capacitor Cm have high impedance due to the parallel resonance circuit including the first capacitor Cm, the first inductor Lm, and the signal amplifier 505 as the magnetic coupling preventing circuit.

The impedance (Zblock) of the magnetic coupling preventing circuit can be expressed in brief by the following expression.

$$\begin{matrix}[ Math . 1 ] & \\ Zblock ∼ \frac{1}{{( 2 π f )}^{2} + {Cm}^{2} + {Z}_{amp}} & ( 1 )\end{matrix}$$

Here, f denotes a frequency and Zamp denotes the magnitude of input impedance of the signal amplifier.

Accordingly, the performance of the magnetic coupling preventing circuit can be enhanced by decreasing the value of Zamp to decrease the value of Cm.

As can been seen from FIG. 13A, the equivalent circuit of the coil elements according to the modified example is also different from the equivalent circuit of the coil unit according to the related art illustrated in FIG. 13B in impedance frequency characteristics of the coil unit when seen from both ends of the first capacitor Cm connected to the signal amplifier 505.

When it is assumed that the same capacitor is employed as the first capacitor Cm, the circuit illustrated in FIG. 13A has characteristics that the input impedance of the coil unit decreases by increasing the proportion of Cc12. Accordingly, when the signal detecting unit 502 is inserted into the central portion of the position at which partial areas of the coil elements are arranged to be adjacent to each other as in this modified example, the input impedance of the coil unit decreases.

Accordingly, when the input impedance of all the coil units is adjusted to 50Ω, it is necessary to adjust the value of the first capacitor Cm for adjusting the input impedance of the coil unit according to the modified example. In this configuration, the input impedance of the coil unit increases when the value of Cm decreases. Accordingly, it is necessary to decrease the value of Cm. As a result, the value of Cm is less than the value of the capacitor Cm in the coil unit according to the related art.

Since the first capacitor Cm with a small capacitance can provide high magnetic coupling on the basis of Expression (1), the coil unit according to this modified example has high magnetic coupling preventing performance.

In this way, according to this modified example, since the circuits around a power supply circuit are changed by arranging the partial area of the coil elements to be adjacent to the signal detecting unit 502, the value of the first capacitor Cm decrease and the magnetic coupling preventing performance is improved as a result. Accordingly, magnetic coupling to another coil unit is reduced and the SNR of an image increases. By constituting the coil unit to have resistance to magnetic coupling, performance of the coil unit is not easily decreased even when the coil unit is deformed.

1. An array coil comprising a plurality of coil units that are each adjusted to receive a magnetic resonance signal from an examinee,
wherein each coil unit includes:
a first coil element and a second coil element of which each is formed of a linear conductor having flexibility with a predetermined length; and
a signal detecting unit that is inserted in series between the first coil element and the second coil element and detects the magnetic resonance signal,
wherein one end of each of the first coil element and the second coil element is connected to the signal detecting unit and the other end thereof is an open end, and
wherein adjacent areas are electromagnetically coupled to each other to function by curving and arranging the first coil element and the second coil element such that at least partial areas on the open end side of the first coil element and the open end side of the second coil element are adjacent to each other with a predetermined gap there between.

2. The array coil according to claim 1, wherein the first coil element and the second coil element have the same length and the open end sides of the first coil element and the second coil element are curved such that the open end sides are arranged to be adjacent to each other in an area other than the signal detecting unit.

3. The array coil according to claim 1, wherein the first coil element and the second coil element have different lengths and the open end sides of the first coil element and the second coil element are curved such that at least one of the first coil element and the second coil element is arranged to be adjacent to the signal detecting unit.

4. The array coil according to claim 1, wherein the first coil element and the second coil element are curved in a ring shape.

5. The array coil according to claim 1, wherein the first coil element and the second coil element are curved in an 8-like shape.

6. The array coil according to claim 1, wherein the first coil element and the second coil element are curved in a rectangular shape.

7. The array coil according to claim 1, further comprising a frequency-adjustment conductor that is provided to be movable on the first coil element and the second coil element,
wherein the frequency-adjustment conductor is a conductor sheet that covers a part of the first coil element and the second coil element.

8. The array coil according to claim 1, wherein the first coil elements and the second coil elements of neighboring coil units of the plurality of coil units are arranged to partially overlap each other in the same plane.

9. A magnetic resonance imaging apparatus comprising:
a static magnetic field forming unit that forms a static magnetic field;
a gradient magnetic field forming unit that forms a gradient magnetic field;
a transmitting RF coil that irradiates an examination object placed in the static magnetic field with an RF magnetic field;
a receiving RF coil that detects a nuclear magnetic resonance signal from the examination object; and
a signal processing unit that processes the nuclear magnetic resonance signal detected by the receiving RF coil,
wherein the receiving RF coil is the array coil according to any one of claim 1.
